(19) United States
(12) Patent Application Publication
(10) Pub. No.: US 2012/0223356 A1
(43) Pub. Date: Sep. 6, 2012

(54) SEMICONDUCTOR LIGHT EMITTING DEVICE AND METHOD FOR MANUFACTURING SAME

(75) Inventor: Takeyuki Suzuki, Kanagawa-ken (JP)

(73) Assignee: KABUSHIKI KAISHA TOSHIBA, Tokyo (JP)

(21) Appl. No.: 13/234,774

(22) Filed: Sep. 16, 2011

(30) Foreign Application Priority Data
Mar. 3, 2011 (JP) 2011-046276

(51) Int. Cl. H01L 33/42

(52) U.S. Cl. 257/99; 438/22; 257/E33.064

(57) ABSTRACT

According to an embodiment, a semiconductor light emitting device includes a first semiconductor layer of a first conductivity type, a second semiconductor layer of a second conductivity type different from the first conductivity type, a light emitting layer provided between the first semiconductor layer and the second semiconductor layer. The device includes a first layer, a first electrode, a second electrode and a third electrode. The first layer is provided on a surface of the second semiconductor layer opposite to the light emitting layer and including conductive oxide. The first electrode is in contact with a part of the first layer and includes a reducible element for reducing the conductive oxide. The second electrode includes a first portion covering the first electrode and a second portion being in contact with the first layer, and the third electrode is electrically connected to the first semiconductor layer.

### CROSS-REFERENCE TO RELATED APPLICATIONS

This application is based upon and claims the benefit of priority from Japanese Patent Application No. 2011-046276, filed on Mar. 3, 2011; the entire contents of which are incorporated herein by reference.

### FIELD

Embodiments are generally related to a semiconductor light emitting device and a method for manufacturing the same.

### BACKGROUND

In order to improve the output of a semiconductor light emitting device, it is effective to improve light extraction efficiency from a semiconductor layer. For example, in an LED (Light Emitting Diode), it is difficult to extract light to the outside, which is emitted under a pad electrode provided to supply an electric current to a light emitting layer. Because of this, a structure is used, in which an electric current block layer is provided beneath the pad electrode to thereby suppress light emission thereunder. However, there may be a case where the presence of the electric current block layer weakens adhesion of the pad electrode thereon.

### BRIEF DESCRIPTION OF THE DRAWINGS

FIG. 1 is a schematic cross-sectional view illustrating a semiconductor light emitting device according to a first embodiment;

FIGS. 2A to 3B are schematic cross-sectional views illustrating manufacturing processes of the semiconductor light emitting device according to the first embodiment;

FIG. 4 is a graph showing a relationship between a content percentage of oxygen in a reactive gas and a sheet resistance of a conductive oxide film;

FIG. 5 is a schematic cross-sectional view illustrating a semiconductor light emitting device according to a second embodiment;

FIG. 6 is a schematic cross-sectional view illustrating a semiconductor light emitting device according to a third embodiment;

FIG. 7A is a partial cross-sectional view schematically illustrating a semiconductor light emitting device according to a comparative example and FIGS. 7B and 7C are images of Scanning Electron microscope showing partial cross-sections thereof.

### DETAILED DESCRIPTION

In general, according to an embodiment, a semiconductor light emitting device includes a first semiconductor layer of a first conductivity type, a second semiconductor layer of a second conductivity type different from the first conductivity type, a light emitting layer provided between the first semiconductor layer and the second semiconductor layer. The device includes a first layer, a first electrode, a second electrode and a third electrode. The first layer is provided on a surface of the second semiconductor layer opposite to the light emitting layer and including conductive oxide. The first electrode is in contact with a part of the first layer and includes a reducible element for reducing the conductive oxide. The second electrode includes a first portion covering the first electrode and a second portion being in contact with the first layer, and the third electrode is electrically connected to the first semiconductor layer.

Hereinafter, embodiments of the invention will be explained with reference to the drawings. In the following embodiments, to the same portion in the drawings, the same numeral is attached and its detailed explanation is omitted appropriately and different portions are explained. Here, in the explanation below, the first conductivity type is an n type and the second conductivity type is a p type and, alternatively, it is also possible to set the first conductivity type to a p type and the second conductivity type to an n type.

### First Embodiment

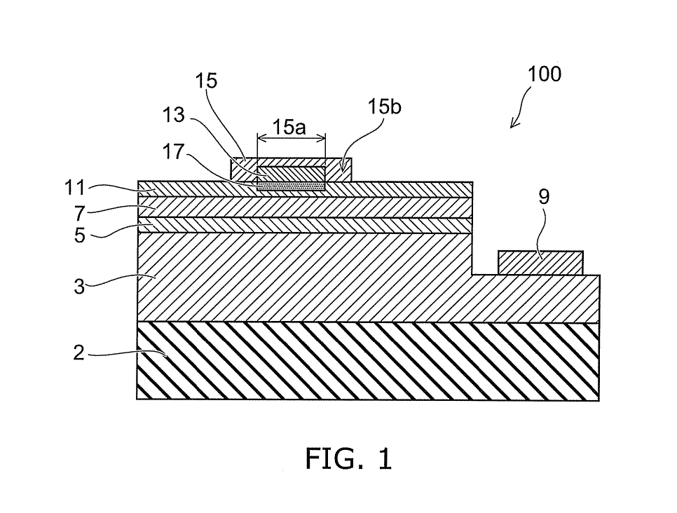

FIG. 1 is a schematic view illustrating a section of a semiconductor light emitting device 100 according to a first embodiment. The semiconductor light emitting device 100 is an LED using a nitride semiconductor as its material. Then, for example, the semiconductor light emitting device 100 comprises an n-type GaN layer 3, which is a first semiconductor layer, a p-type GaN layer 7, which is a second semiconductor layer, and a light emitting layer 5 provided between the n-type GaN layer 3 and the p-type GaN layer 7.

The light emitting layer 5 includes a quantum well configured with a GaN barrier layer and an InGaN well layer, for example. Then, the n-type GaN layer 3, the light emitting layer 5, and the p-type GaN layer 7 are provided on a sapphire substrate 2 in this order.

Further, a transparent electrode 11 is provided on the surface of the p-type GaN layer 7 opposite to the light emitting layer 5. The transparent electrode 11, which is a first layer, includes conductive oxide, such as ITO (Indium Tin Oxide).

A p electrode 15 is provided on the surface of the transparent electrode 11. Then, a reducible electrode 13 is provided as a first electrode between the p electrode 15 and the transparent electrode 11. The reducible electrode 13 includes a material that comes into contact with a part of the transparent electrode 11 and which reduces the conductive oxide included in the transparent electrode 11. Then, as shown in FIG. 1, the p electrode 15, which is a second electrode, has a pad portion 15a, which is a first portion that covers the surface of the reducible electrode 13, and a contact portion 15b, which is a second portion that comes into contact with the transparent electrode 11.

Further, an electric current block region 17 is provided at the portion where the reducible electrode 13 comes into contact with the transparent electrode 11. The electric current block region 17 extends in the direction from the surface of the transparent electrode 11 toward the p-type GaN layer 7. The electric current block region 17 is formed as a region where the conductive oxide is reduced and a resistance of the conductive oxide becomes higher than that in other portions of the transparent electrode 11.

In contrast, an n electrode 9, which is a third electrode, is provided on the surface of the n-type GaN layer 3 exposed by selectively removing the p-type GaN layer 7 and the light emitting layer 5. The n electrode 9 is electrically connected to the n-type GaN layer 3.

The semiconductor light emitting device 100 operates under a drive current flowing between the p electrode 15 and the n electrode 9. The drive current is supplied via metal wires (not shown) bonded to the pad portion 15a of the p electrode 15 and the n electrode 9, respectively. The p electrode 15 is electrically connected to the transparent electrode 11 at the contact portion 15b. Then, the drive current flows from the p electrode 15 to the n electrode 9 via the transparent electrode 11, the p-type GaN layer 7, the light emitting layer 5, and the n-type GaN layer 3. Thereby, holes are injected into the light emitting layer 5 from the p-type GaN layer 7 and electrons from the n-type GaN layer 3 and the light emitting layer 5 emits blue light.

For example, the transparent electrode 11 including ITO as the conductive oxide transmits visible light. Consequently, light emitted from the light emitting layer 5 can be extracted to the outside via the transparent electrode. In contrast, the p electrode 15 includes, for example, nickel (Ni) and gold (Au). Consequently, the p electrode 15 does not transmit light, and thus, it is not possible to extract light emitted from the light emitting layer 5 beneath the p electrode 15.

Hence, in the semiconductor light emitting device 100, the electric current flowing beneath the p electrode 15 is reduced by providing the high-resistance electric current block region 17, and thus light emission in the light emitting layer 5 is suppressed beneath the p electrode 15. Thereby, the light emission increases in the region where the p electrode 15 is not provided on the light emitting layer 5 and it is possible to improve light extraction efficiency of light emitted from the light emitting layer 5.

Furthermore, the p electrode 15 may include a thin wire electrode (not shown), which extends from the pad portion 15a toward a periphery of the transparent electrode 11, in order to reinforce the electric current spreading. In such a case, the thin wire electrode can also include the reducible portion and the high-resistance electric current block region provided therebeneath.

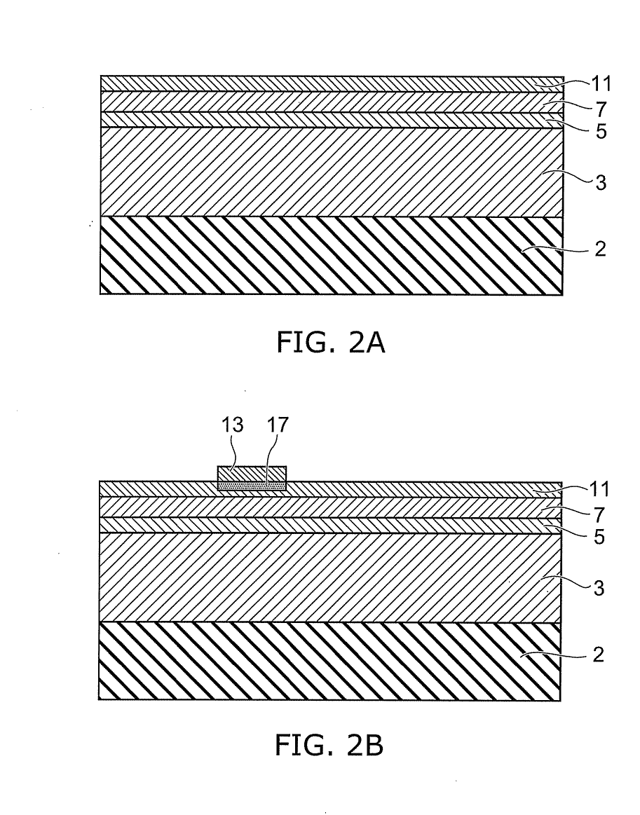

Next, the manufacturing process of the semiconductor light emitting device 100 will be explained with reference to FIGS. 2 and 3. Each cross-sectional view in FIG. 2 and FIG. 3 schematically shows a partial section of a wafer in each process.

FIG. 2A shows a step where the n-type GaN layer 3, the light emitting layer 5, the p-type GaN layer 7 and the transparent electrode 11 are provided sequentially on the sapphire substrate 2. The n-type GaN layer 3, the light emitting layer 5 and the p-type GaN layer 7 are formed using, for example, the MOCVD (Metal Organic Chemical Vapor Deposition) method. The transparent electrode 11 is formed using, for example, the sputter method.

A SiC substrate, a GaN substrate, a Si substrate or the like can be used in place of the sapphire substrate 2. Further, it may also be possible to form an undoped GaN buffer layer between the sapphire substrate 2 and the n-type GaN layer 3.

In place of the ITO, the transparent electrode 11 may include other conductive oxide, such as ZnO (zinc oxide), TiO (titanium oxide), NiO (nickel oxide) or the like.

Next, as shown in FIG. 2B, the reducible electrode 13 is formed selectively on the surface of the transparent electrode 11. The reducible electrode 13 includes an element having strong reducing properties, such as aluminum (Al), nickel (Ni) and magnesium (Mg), that is, an element having strong so-called ionization tendency. Furthermore, the reducible electrode 13 may include carbide and hydride. For example, a metal film including the above-mentioned reducible element is formed by the sputter method or the vacuum deposition method and then it is patterned into a predetermined shape using photolithography.

Subsequently, the transparent electrode 11 and the reducible electrode 13 are thermally processed in contact therewith. For example, the wafer are processed in a nitrogen atmosphere, where the transparent electrode 11 and the reducible electrode 13 are formed thereon, using a thermal processing furnace set to a temperature range from 300° C. to 700° C. Thereby, the electric current block region 17 is formed in the direction from the surface of the transparent electrode 11 toward the p-type GaN layer 7, where the reducible electrode 13 is in contact with the transparent electrode 11. That is, the resistance increases in the transparent electrode 11 where the strongly reducible element in the reducible electrode 13 takes oxygen from the conductive oxide. Consequently, the electric current block region 17 is formed having a resistance higher than that of other portions in the transparent electrode 11.

Next, as shown in FIG. 3A, the p electrode 15 is formed covering the reducible electrode 13. As described earlier, the p electrode 15 may include a multilayer film in which, for example, Ni and Au are stacked sequentially. The multilayer film of Ni/Au can be formed using, for example, the vacuum deposition method. Then, it is patterned into a shape which includes the pad portion 15a covering the reducible electrode 13 and the contact portion 15b in contact with the transparent electrode 11.

In the case where the p electrode 15 includes the multilayer film of Ni/Au, the transparent electrode 11 and the Ni film come into contact with each other in the contact portion 15b, but Ni contained in the film does not reduce the conductive oxide in the transparent electrode 11 unless it is subjected to thermal processing at a predetermined temperature or higher. Consequently, it is possible to form an ohmic contact between the transparent electrode 11 and the p electrode 15. That is, an electrical contact between the transparent electrode 11 and the p electrode 15 is formed at a temperature lower than the temperature of the thermal processing to form the electric current block region 17.

Next, as shown in FIG. 3B, the transparent electrode 11 is selectively etched from the surface to the n-type GaN layer 3 in order to expose the surface of the n-type GaN layer 3. For example, the transparent electrode 11, the p-type GaN layer 7 and the light emitting layer 5 are removed using a resist film as an etching mask by the RIE (Reactive Ion Etching) method.

Subsequently, the n electrode 9 is formed on the surface of the n-type GaN layer 3. For example, a multilayer film of titanium (Ti) and Al are stacked sequentially thereon using the sputter method and patterned into a predetermined shape.

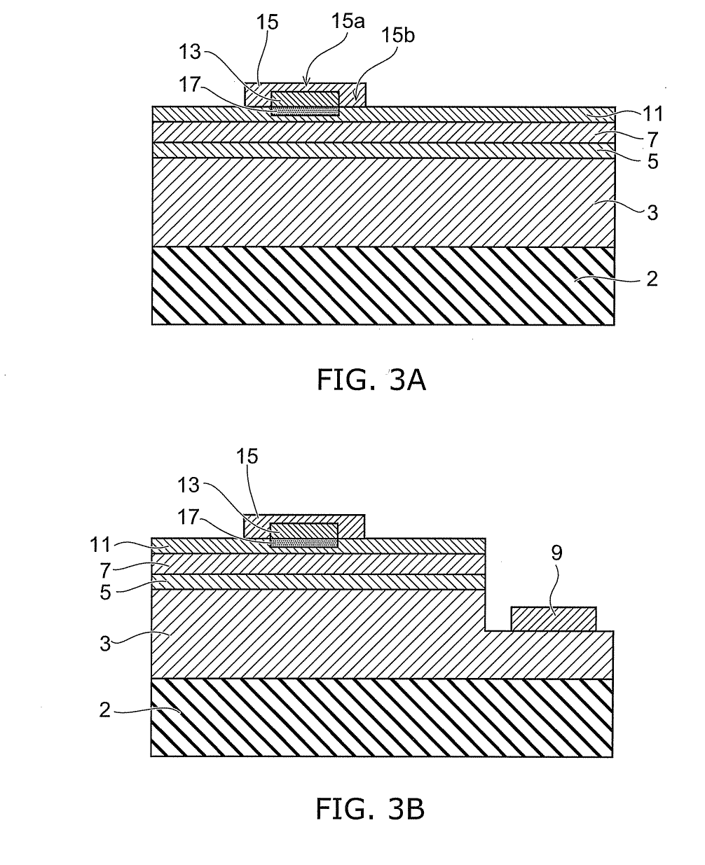

Next, the electric current block region 17 will be explained. FIG. 4 is a graph showing a relationship between the sheet resistance of the ITO film and the content percentage of oxygen in the reactive gas in the forming process thereof. The horizontal axis represents the content percentage of the oxygen gas and the vertical axis represents the sheet resistance of ITO.

The ITO film can be formed using the sputter method. For example, an ITO film is formed on the surface of a wafer by sputtering an ITO target with Ar ions. At this time, the sheet resistance of the ITO film can be controlled by mixing an argon gas (Ar), which is the sputter gas, with an oxygen gas (O₂).

As shown in FIG. 4, when the oxygen gas is not mixed, the sheet resistance of the ITO film becomes 500 Ω/square. The resistance of the ITO film reduces as the content percentage of the oxygen gas increases and at 0.6 to 0.7%, the sheet resistance reaches its local minimum. As described above, the resistance of the ITO film is sensitive to the amount of oxygen included therein.

That is, the graph shown in FIG. 4 indicates that the resistance of the ITO film can be increased by reducing ITO included in the transparent electrode 11, i.e. taking oxygen therefrom. Consequently, as shown in the embodiment, the electric current block region 17 can be formed by providing the reducible electrode 13 under the pad portion 15a of the p electrode 15 and subjecting it to thermal processing. Then, as described earlier, the electric current block region 17 suppresses the electric current flowing beneath the p electrode 15 and improves the light extraction efficiency of light emitted from the light emitting layer 5.

Further, the semiconductor light emitting device 100 according to the embodiment improves the reliability of the electric current block structure provided under the p electrode 15.

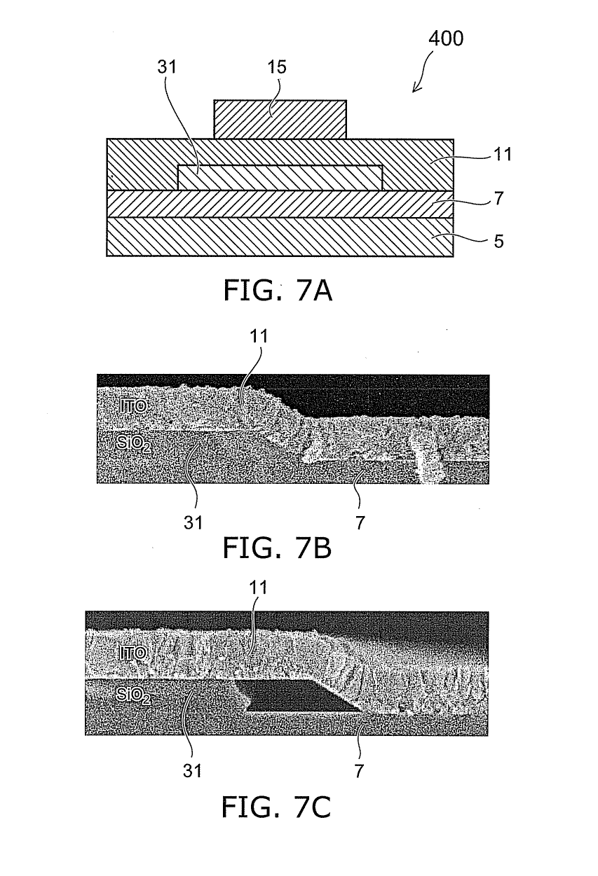

For example, FIG. 7 shows a partial section of a semiconductor light emitting device 400 according to a comparative example. FIG. 7A is a schematic cross-sectional view showing the structure of the p electrode 15. FIGS. 7B and 7C are electron microscopic photos thereof.

As shown in FIG. 7A, in the semiconductor light emitting device 400, an electric current block layer 31 is provided selectively on the surface of the p-type GaN layer 7. The electric current block layer 31 is, for example, a silicon oxide film (SiO₂). Then, the transparent electrode 11 is provided so as to cover the electric current block layer 31. Further, the p electrode 15 is provided on the electric current block layer 31 via the transparent electrode 11.

FIG. 7B is an image of Scanning Electron Microscope (SEM) showing a part of a cross-section of the electric current block layer 31 in the manufacturing process of the semiconductor light emitting device 400. This shows a state where the electric current block layer 31 is provided on the p-type GaN layer 7 and the ITO film, which is the transparent electrode 11, is formed thereon.

FIG. 7C is a SEM image showing a part of the cross-section of the electric current block layer 31 in a step following the step shown in FIG. 7B. Here, there is a hollow between the p-type GaN layer 7 and the transparent electrode 11, produced by moving back the edge of the electric current block layer 31. The etching liquid infiltrating through the ITO film may etch the edge of the electric current block layer 31, forming such a hollow.

For example, cracks are likely to occur in the ITO film formed on an abrupt edge of the electric current block layer 31. As shown in FIG. 7B, there may be a case where cracks occur at the inclined edge of the electric current block layer 31, though the unevenness is relaxed. Then, it can be thought that the etching liquid has infiltrated through the cracks after the ITO film is formed.

The hollow that appears in FIG. 7C may weaken the adhesion of the transparent electrode 11 and, for example, cause peeling off the p electrode 15 at the time of wire bonding. That is, the semiconductor light emitting device 400 according to the comparative example has a poor reliability in the electric current block structure.

In contrast, in the semiconductor light emitting device 100 according to the embodiment, the transparent electrode 11 is formed on the flat surface of the p-type GaN layer 7. Consequently, it is possible to suppress the occurrence of defects, such as cracks, in the conductive oxide included in the transparent electrode 11. As a result, it is possible to prevent the reduction in adhesion strength of the transparent electrode 11 and to improve the reliability of the electric current block structure.

There may be a case where, for example, fine bumps and dips are provided on the surface of the p-type GaN layer in order to improve light extraction efficiency. In such a case also, adopting the electric current block structure may avoid the reduction in adhesion strength of the transparent electrode 11 and improve reliability thereof, in which the transparent electrode 11 is formed on the p-type GaN layer and the reducible electrode 13 provided on the transparent electrode 11.

### Second Embodiment

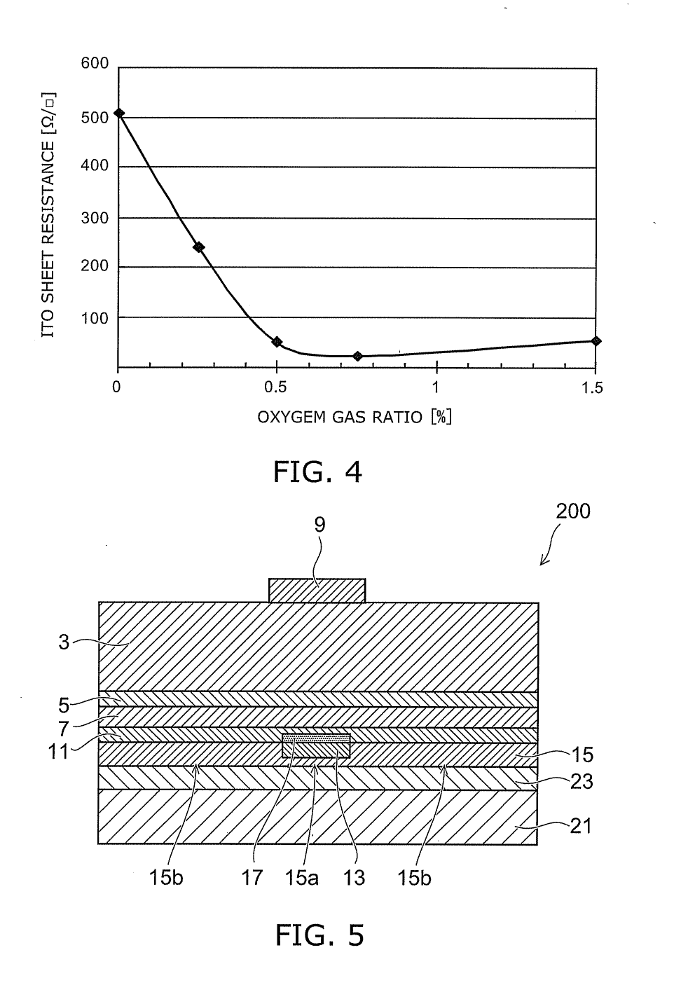

FIG. 5 is a schematic cross-sectional view illustrating a semiconductor light emitting device 200 according to a second embodiment. The semiconductor light emitting device 200 is a light emitting device called a thin film LED and includes a stacked body of the n-type GaN layer 3, the light emitting layer 5 and the p-type GaN layer 7, which is transferred from the sapphire substrate 2 to a support substrate 21.

As shown in FIG. 5, the p electrode 15, the transparent electrode 11, the p-type GaN layer 7, the light emitting layer 5 and the n-type GaN layer 3 are provided on the support substrate 21 via a joint metal 23. Then, the n electrode 9 is selectively provided on the surface of the n-type GaN layer 3. The support substrate 21 may be a p-type silicon substrate for example.

The reducible electrode 13 is selectively provided between the p electrode 15 and the transparent electrode 11, forming the electric current block region 17. The p electrode 15 has the first portion (the pad portion 15a) that covers the reducible electrode 13 and the contact portion 15b that is the second portion with which the transparent electrode 11 comes into contact.

In the semiconductor light emitting device 200, the p electrode 15 functions as a reflective electrode that reflects light emitted from the light emitting layer 5. Then, a part of the light emitted from the light emitting layer 5, which propagates to the p electrode 15 side, is reflected from the p electrode 15 in the direction of the n-type GaN layer 3. That is, the light emitted from the light emitting layer 5 is extracted from the n-type GaN layer 3 side where the sapphire substrate 2 is removed. Thereby, it is possible to improve the light extraction efficiency. Then, the electric current block region 17 facing the n electrode 9 via the stacked body suppresses light emission of the light emitting layer 5 beneath the n electrode 9, and thus it is possible to further improve extraction efficiency.

In the semiconductor light emitting device 200 according to the embodiment, the transparent electrode 11 is formed on the flat surface of the p-type GaN layer 7, and thus it is also possible to improve its adhesion. Then, it becomes possible to improve reliability of the electric current block structure.

In the first and second embodiments described above, the LED is explained to include the n-type GaN layer 3 and the p-type GaN layer 7, but it is also possible to set a configuration by appropriately combining a GaN-based nitride semiconductor expressed by a composition formula InₓAl_{y}Ga_{1-x-y}N (0≦x≦1, 0≦y≦1, 0≦x+y≦1). Furthermore, it may also be possible to insert a block layer to prevent overflow of electrons between the p-type GaN layer 7 and the light emitting layer 5 and to provide a superlattice layer between the n-type GaN layer 3 and the light emitting layer 5.

Further, it is possible to apply the first and second embodiments described above to a semiconductor light emitting device using other materials, such as InGaAlP (InₓGa_{y}Al_{1-x-y}P: 0≦x≦1, 0≦y≦1, 0≦x+y≦1) and GaAlAs (GaₓAl₁₋ₓAs: 0≦x≦1) not limited to the nitride semiconductor.

### Third Embodiment

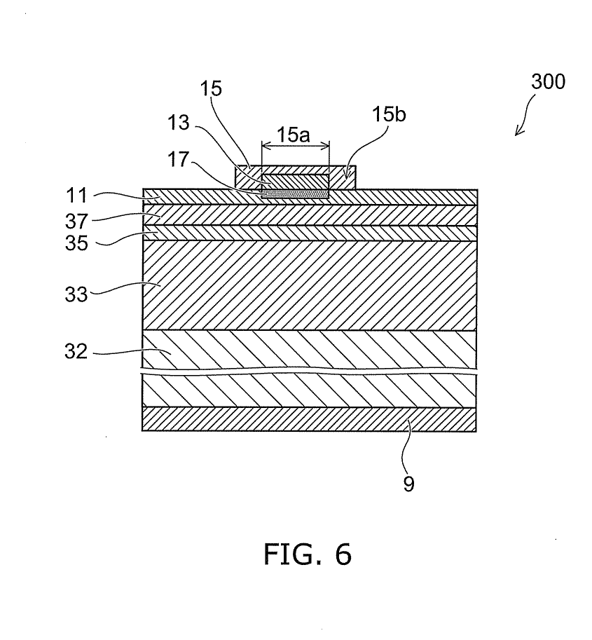

FIG. 6 is a schematic view showing a sectional structure of a semiconductor light emitting device 300 using InGaAlP as a material. For example, in an LED using InGaAlP, an n-type GaAs substrate 32 is used in place of the sapphire substrate 2 in FIG. 1. Then, on the n-type GaAs substrate 32, an n-type InGaAlP layer 33, a light emitting layer 35 and a p-type InGaAlP layer 37 are provided. The light emitting layer 35 includes a quantum well configured by an InGaP well layer and an InGaAlP barrier layer.

Further, as in the semiconductor light emitting device 100 shown in FIG. 1, the transparent electrode 11, the reducible electrode 13 and the p electrode 15 are provided on the p-type InGaAlP layer 37. Then, by performing thermal processing, the electric current block region 17 is formed within the transparent electrode 11. In contrast, different from the sapphire substrate 2, the n-type GaAs substrate 32 has conductivity. Consequently, it is possible to form the n electrode 9 on the back surface of the n-type GaAs substrate 32.

In the semiconductor light emitting device 300 according to the embodiment, the transparent electrode 11 is formed on the surface of the p-type InGaAlP layer 37 having a flat surface. Thus, the adhesion of the transparent electrode 11 is improved and, thereby, it becomes possible to improve reliability of the electric current block structure.

Further, it is also possible to form the same thin film structure as that of the semiconductor light emitting device 200 shown in FIG. 5. That is, after forming the transparent electrode 11, the reducible electrode 13, the p electrode 15, and the electric current block region 17, the n-type InGaAlP layer 33, the light emitting layer 35 and the p-type InGaAlP layer 37 are transferred from the n-type GaAs substrate 32 to a p-type silicon substrate. Then, it is possible to constitute the thin film LED.

In the specification of the application, it is assumed that the “nitride semiconductor” includes a III-V group compound semiconductor of BₓIn_{y}Al_{z}Ga_{1-x-y-z}N (0≦x≦1, 0≦y≦1, 0≦z≦1, 0≦x+y+z≦1) and further the V group element includes a mixed crystal containing phosphorus (P) and arsenic (As) in addition to N (nitrogen). Furthermore, those including various elements to be added to control various physical properties, such as conductivity, and those including various elements included unintentionally are also included in the “nitride semiconductor”.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor light emitting device comprising:
a first semiconductor layer of a first conductivity type;
a second semiconductor layer of a second conductivity type different from the first conductivity type;
a light emitting layer provided between the first semiconductor layer and the second semiconductor layer;
a first layer provided on a surface of the second semiconductor layer opposite to the light emitting layer and including conductive oxide;
a first electrode being in contact with a part of the first layer and including a reducible element for reducing the conductive oxide;
a second electrode including a first portion covering the first electrode and a second portion being in contact with the first layer; and
a third electrode electrically connected to the first semiconductor layer.

2. The device according to claim 1, wherein the first layer includes a region extending in a direction from the surface of the first layer beneath the first electrode toward the second semiconductor layer and having a resistance higher than that of other part of the first layer.

3. The device according to claim 1, wherein the first electrode is a metal containing the reducible element.

4. The device according to claim 1, wherein the first electrode is a metal containing at least one of Al, Ni and Mg.

5. The device according to claim 1, wherein the first layer includes a region extending in a direction from the surface of the first layer beneath the first electrode toward the second semiconductor layer and having a resistance higher than that of other part of the first layer, and the first electrode is a metal including at least one of Al, Ni and Mg.

6. The device according to claim 1, wherein the first electrode increases the resistance of the first layer by taking oxygen from the conductive oxide included in the first layer.

7. The device according to claim 1, wherein the first electrode includes carbide or hydride.

8. The device according to claim 1, wherein the first layer includes at least one of ITO, ZnO, TiO, and NiO.

9. The device according to claim 1, wherein each of the first semiconductor layer, the second semiconductor layer and the light emitting layer includes InₓGa_{y}Al_{1-x-y}N (0≦x≦1, 0≦y≦1, 0≦x+y≦1).

10. The device according to claim 1, wherein each of the first semiconductor layer, the second semiconductor layer and the light emitting layer includes InₓGa_{y}Al_{1-x-y}P (0≦x≦1, 0≦y≦1, 0≦x+y≦1).

11. The device according to claim 1, wherein each of the first semiconductor layer, the second semiconductor layer and the light emitting layer includes AlₓGa₁₋ₓAs (0≦x≦1).

12. The device according to claim 1, wherein the first layer transmits light emitted from the light emitting layer.

13. The device according to claim 1, further comprising:
an insulating substrate on a side of the first semiconductor layer opposite to the light emitting layer,
wherein the third electrode, the first electrode and the second electrode are provided on the same side of the insulating substrate.

14. The device according to claim 1, further comprising:
a conductive substrate between the first semiconductor layer and the third electrode,
wherein the third electrode is provided on the surface of the first semiconductor layer opposite to the first semiconductor layer.

15. The device according to claim 1, wherein the first portion of the second electrode is a pad portion, a metal wire is bonded on the pad portion, and the second portion is a contact portion electrically connected to the first layer.

16. The device according to claim 1, wherein the second electrode reflects light emitted from the light emitting layer in the direction of the first semiconductor layer, and the third electrode selectively provided on the surface of the first semiconductor layer opposite to the light emitting layer, the third electrode facing the first electrode via the first semiconductor layer, the light emitting layer and the second semiconductor layer.

17. A method for manufacturing a semiconductor light emitting device including a first semiconductor layer, a second semiconductor layer and a light emitting layer provided between the first semiconductor layer and the second semiconductor layer, comprising:
forming a first layer including conductive oxide on a surface of the second semiconductor layer opposite to the light emitting layer;
selectively forming a first electrode containing a reducible element for reducing the conductive oxide on the first layer;
forming a region extending in the direction from a surface of the first layer beneath the first electrode toward the second semiconductor layer by a thermal treatment, the region having a resistance higher than that of other part of the first layer;
forming a second electrode including a first portion covering the first electrode and a second portion being in contact with the first layer; and
forming a third electrode electrically connected to the first semiconductor layer.

18. The method according to claim 17, further comprising:
forming an electric contact between the first layer and the second portion of the second electrode at a temperature lower than the temperature in the thermal treatment.
